(19) United States
(12) Patent Application Publication
(10) Pub. No.: US 2005/0248042 A1
(43) Pub. Date: Nov. 10, 2005

(54) Semiconductor memory device

(76) Inventors: Jong-Eon Lee, Suwon-si (KR); Chul-Soo Kim, Suwon-si (KR); Byung-Hoon Jeong, Suwon-si (KR); Jun-Hyung Kim, Yongin-si (KR); Young-Sun Min, Seoul (KR)

Correspondence Address: MYERS BIGEL SIBLEY & SAJOVEC, PO BOX 37428, RALEIGH, NC, 27627, US

(21) Appl. No.: 11/121,864

(22) Filed: May 4, 2005

(30) Foreign Application Priority Data
May 4, 2004 (KR) 2004-31470
Jun. 28, 2004 (KR) 2004-49168
Jan. 14, 2005 (KR) 2005-3857

(51) Int. Cl. H01L 27/108

(52) U.S. Cl. 257/907

(57) ABSTRACT

A semiconductor memory device having a memory cell array includes a plurality of first signal lines arranged on the memory cell array in the same direction and a plurality of second signal lines arranged on the memory cell array in a perpendicular direction to the first signal lines. The first signal lines are alternately arranged on at least two layers, and the second signal lines are arranged on a layer where the first signal lines are not arranged.

### CROSS-REFERENCE TO RELATED APPLICATIONS

This application claims the benefit of Korean Patent Application No. 2004-31470, filed May 4, 2004, Korean Patent Application No. 2004-49168, filed Jun. 28, 2004, and Korean Patent Application No. 2005-03857, filed Jan. 14, 2005, the disclosures of which are hereby incorporated herein by reference in their entirety.

### FIELD OF THE INVENTION

The present invention relates to a semiconductor memory device and, more particularly, to a semiconductor memory device which can operate at high speed which having high capacity and high integration.

### BACKGROUND OF THE INVENTION

In general, a semiconductor memory device has a memory cell array region and a peripheral circuit region, and signal lines (e.g., word line selecting signal line and column selecting signal line) for receiving/outputting data are arranged on two layers above the regions. As the semiconductor memory device purses high integration and high speed, the number of data lines is more increased, leading to large layout area size. FIG. 1 is a schematic view illustrating a memory cell array of a conventional semiconductor memory device. In FIG. 1, 10 denotes a memory cell array, 20 denotes a column decoder, 30 denotes a low decoder, CJ denotes a conjunction region, SWD denotes a sub word line driver region, S/A denotes a sense amplifier region, and SMCA denotes a sub memory cell array region. Also, NWE denotes a plurality of word line enable signal lines, CSL denotes a plurality of column selecting signal lines, LIO denotes a plurality of local data IO lines, and GIO denotes a plurality of global data IO lines.

In the memory cell array 10 of FIG. 1, a block having the conjunction region CJ, the sub word line driver region SWD, the sense amplifier region S/A, and the sub memory cell array region SMCA is repetitively arranged in transverse and longitudinal directions. A control signal generating circuit for controlling a sub word line driver and a control signal generating circuit for controlling a sense amplifier are arranged in the conjunction region CJ, the sub word line drivers are arranged in the sub word line driver region SWD, and the sense amplifiers are arranged in the sense amplifier region S/A.

Functions of the components of FIG. 1 will be described below. The memory cell array 10 includes memory cells MC connected between a sub word line SWL and a bit line BL and writes/reads data onto/from a memory cell MC which is selected in response to a signal transmitted to the word line enable signal line NWE and a signal transmitted to the column selecting signal line CSL. The column decoder 20 decodes a column address CA to generate column selecting signals for selecting a certain column selecting signal line CSL. The row decoder 30 decodes a row address RA to generate word line enable signals for selecting a certain word line enable signal line NWE. The word line enable signal line NWE is arranged above the sub word line driver region SWD and the sub memory cell array region SMCA in a longitudinal direction. The local data 10 line LIO is arranged above the conjunction region CJ and the sense amplifier region S/A in the same direction NWE as the word line enable signal line NWE. The column selecting signal line CSL and the global data 10 line GIO are arranged above the sense amplifier region S/A and the sub memory cell array region SMCA in a perpendicular direction to the word line enable signal line NWE.

FIG. 2 is a circuit diagram illustrating a connection structure of the semiconductor memory device of FIG. 1. Referring to FIG. 2, bit lines BL and /BL are connected to a drain of column selecting transistors TR1 and TR2, local data IO lines LIO and /LIO are connected to a source of the column selecting transistors TR1 and TR2, and the column selecting signal line CSL is connected to a gate of the column selecting transistors TR1 and TR2. A signal transmitted to the column selecting signal line CSL controls operation of the column selecting transistors TR1 and TR2 to thereby transfer/block out data between the bit lines BL and /BL and the local data IO lines LIO and /LIO. That is, the column selecting signal line CSL is arranged to cross the whole region of the memory cell array to be connected to a plurality of column selecting transistors TR1 and TR2 and operate operation of a plurality of column selecting transistors TR1 and TR2, respectively.

However, if area size of the memory cell array 10 is increased, the column selecting signal line CSL that is arranged throughout the whole region of the memory cell array 10 is increased in length. Thus, if length of the column-selecting signal line CSL is increased, electrical resistance (i.e., loading) of the column selecting signal line CSL is also increased. Even though not described above, such phenomenon happens in the other signal lines, which are arranged throughout the whole region of the memory cell array 10 as well as in the column selecting signal line CSL.

FIG. 3 is a schematic view illustrating signal line arrangement of the semiconductor memory device of FIG. 1. In FIGS. 1 and 3, like references denote like blocks and lines. Non-hatched lines are metal lines, which are arranged on a first layer, and hatched lines are metal lines, which are arranged on a second layer. That is, a first metal layer is formed by metal lines arranged on the first layer, and a second metal layer is formed by metal lines arranged on the second layer, so that signal lines and power lines are arranged on the two metal layers.

Signal line arrangement of FIG. 3 will be described below. The word line enables signal lines NWE and the local data IO lines LIO are arranged on the first layer in a longitudinal direction. First power lines PL1 are arranged on the first layer in the same direction as the word line enable signal line NWE in a space between the word line enable signal line NWE and the local data 10 line LIO. The column selecting signal lines CSL and the global data IO lines GIO are arranged on the second layer in a perpendicular direction to the word line enable signal lines NWE, i.e., transverse direction. Second power lines PL2 are arranged on the second layer in the same direction as the column selecting signal line CSL in a space between the column selecting signal line CSL and the global data IO lines GIO. That is, the word line enable signal lines NWE, the local data IO lines LIO, and the first power lines PL1 are arranged on the first layer in the same direction, and the column selecting signal lines CSL, the global data IO lines GIO, and the second power lines PL2 are arranged on the second layer in a perpendicular direction to the word line enable signal line NWE.

The number of the signal lines arranged in a way described above, i.e., the word line enable signal lines NWE and the column signal lines CSL is determined by address coding of the column decoder 20 and the row decoder 30. Here, the number of the signal lines is more increased as the semiconductor memory device is higher integrated and has higher capacity. That is, as the semiconductor memory device is higher integrated and has higher capacity, the number of the signal lines to be arranged in the restricted area of the memory cell array is more increased. Thus, there is a limitation to processing margin for the number of the signal lines which can be formed, and so width of the signal lines and interval between the signal lines are decreased, so that loading and coupling effect of the signal lines are increased. If loading and coupling effect of the signal lines are increased, a signal, which is transmitted through the signal lines, has error information due to increased delay time and increased coupling effect, whereby operation characteristics of the semiconductor memory device are degraded. For the foregoing reasons, since line width and line interval of the signal lines are more decreased and length of the signal lines is more increased as the semiconductor memory device is higher integrated and has higher capacity, the conventional semiconductor memory device has a problem in that it can not support high speed operation stably.

### SUMMARY OF THE INVENTION

It is an object of the present invention to provide a semiconductor memory device, which can stably support high-speed operation even thought it, is high integrated and high capacity.

In a first aspect of the present invention, a semiconductor memory device having a memory cell array, includes: a plurality of first signal lines arranged on the memory cell array in the same direction; and a plurality of second signal lines arranged on the memory cell array in a perpendicular direction to the first signal lines, wherein the first signal lines are alternately arranged on at least two metal layers, and the second signal lines are arranged on a metal layer where the first signal lines are not arranged.

In a second aspect of the present invention, a semiconductor memory device having a memory cell array, includes: a plurality of first signal lines, each of the plurality of firs signal line including a first line and a second line which are arranged on different metal layers on the memory cell array; and a plurality of second signal line arranged on a metal layer where the first signal line are not arranged in a perpendicular direction to the first signal lines on the memory cell array, wherein the first line of the first signal line is arranged between the second lines of the same first signal line and between the second lines of the adjacent first signal lines, and the second line is arranged between the first lines of the same first signal line and between the first lines of the adjacent first signal lines.

In a third aspect of the present invention, a semiconductor memory device having a memory cell array, includes: a plurality of first signal lines, each of the plurality of the first signal lines including a lower line and an upper line which are arranged on different layers above the memory cell array; and a plurality of second signal lines which are arranged on a layer where the first signal lines are not arranged, in a perpendicular direction to the first signal lines above the memory cell array, wherein the upper line of the first signal line is arranged to overlap the lower line of the same first signal line.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a schematic view illustrating a memory cell array of a conventional semiconductor memory device;

FIG. 2 is a circuit diagram illustrating a connection structure of the semiconductor memory device of FIG. 1;

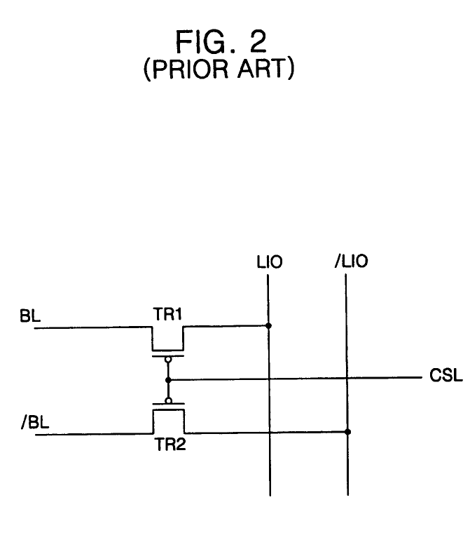

FIG. 3 is a schematic view illustrating signal line arrangement of the semiconductor memory device of FIG. 1;

FIG. 4 is a schematic view illustrating signal line arrangement of a semiconductor memory device according to a first embodiment of the present invention;

FIG. 5 is a schematic view illustrating signal line arrangement of a semiconductor memory device according to a second embodiment of the present invention;

FIG. 6 is a schematic view illustrating signal line arrangement of a semiconductor memory device according to a third embodiment of the present invention;

FIG. 7 is a schematic view illustrating signal line arrangement of a semiconductor memory device according to a fourth embodiment of the present invention;

FIG. 8 is a schematic view illustrating signal line arrangement of a semiconductor memory device according to a fifth embodiment of the present invention;

FIG. 9 is a schematic view illustrating signal line arrangement of a semiconductor memory device according to a sixth embodiment of the present invention;

FIG. 10 is a schematic view illustrating signal line arrangement of a semiconductor memory device according to a seventh embodiment of the present invention;

FIG. 11 is a schematic view illustrating signal line arrangement of a semiconductor memory device according to an eighth embodiment of the present invention;

FIGS. 12A and 12B are schematic views illustrating signal line arrangement of a semiconductor memory device according to a ninth embodiment of the present invention;

FIGS. 13A and 13B are schematic views illustrating signal line arrangement of a semiconductor memory device according to a tenth embodiment of the present invention; and

FIGS. 14A and 14B are schematic views illustrating signal line arrangement of a semiconductor memory device according to an eleventh embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout the specification.

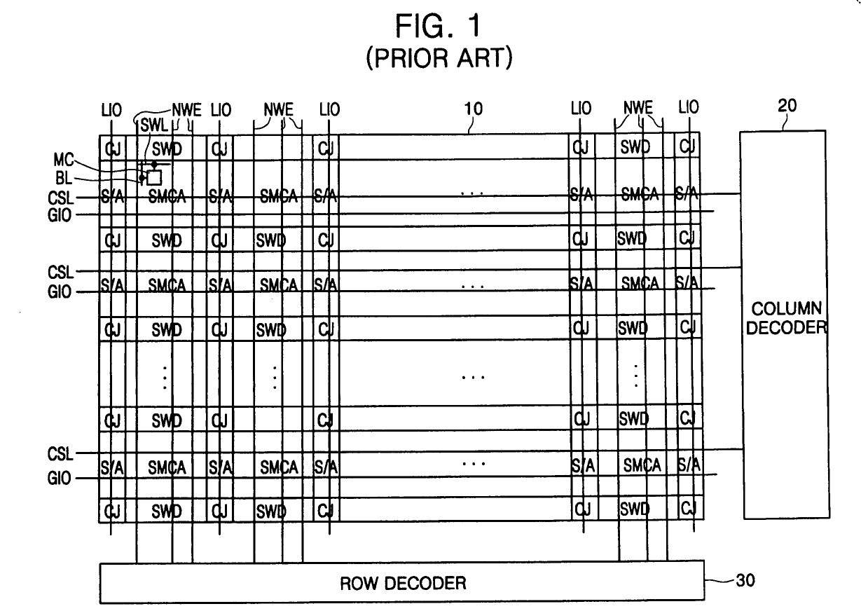

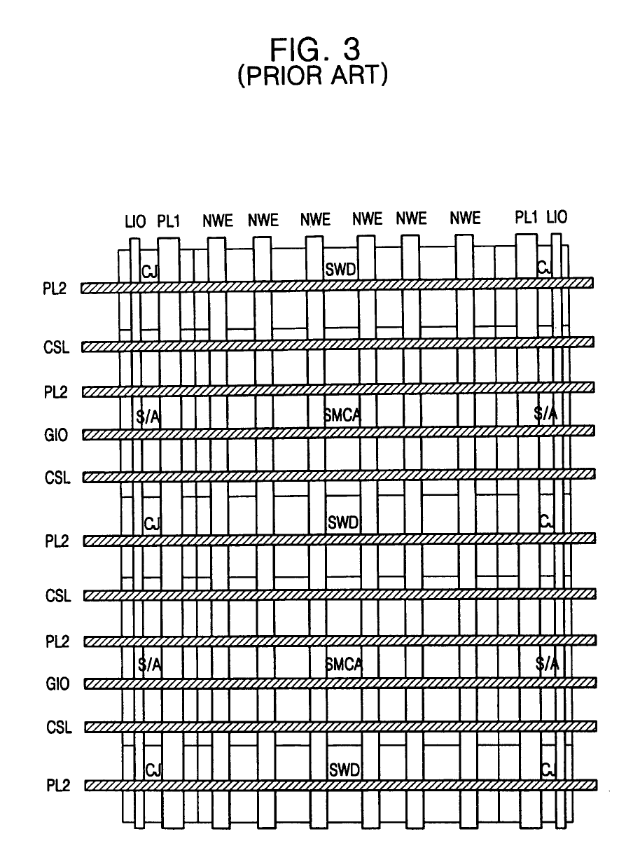

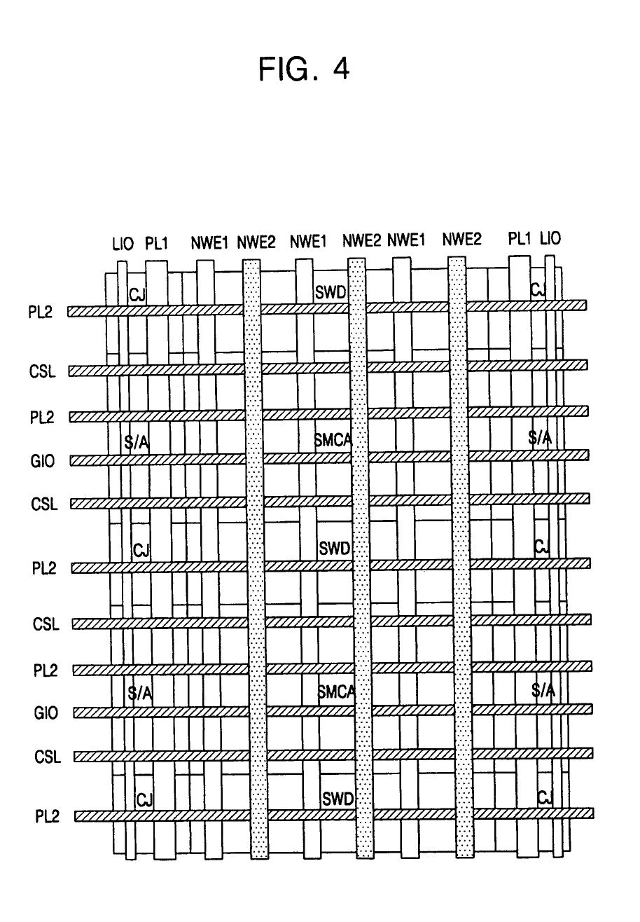

FIG. 4 is a schematic view illustrating a signal line arrangement of a semiconductor memory device according to a first embodiment of the present invention. In FIGS. 1 and 4, like references denote like blocks and lines. Non-hatched lines are metal lines which are arranged on a first layer, hatched lines are metal lines which are arranged on a second layer, and dotted lines are metal lines which are arranged on a third layer. That is, a first metal layer is formed by metal lines arranged on the first layer, a second metal layer is formed by metal lines arranged on the second layer, and a third metal layer is formed by metal lines arranged on the third layer, so that signal lines and power lines are arranged on the three metal layers. In FIG. 4, the local data 10 lines LIO and the first power lines PL1 are arranged on the first layer in the same way as those of FIG. 3, and the column selecting signal lines CSL and the second power lines PL2 are arranged on the second layer in the same way as those of FIG. 3. The word line enable signal lines NWE are alternately arranged on the first and third layers. That is, the word line enable signal lines NWE include first word line enable signal lines NWE1 and second word line enable signal lines NWE2 which are arranged to be alternated in a transverse direction. The first word line enable signal lines NWE1 are arranged on the first layer in a longitudinal direction, and the second word line enable signal lines NWE2 are arranged on the third layer in a longitudinal direction. The signal line arrangement of FIG. 4 is suitable for a semiconductor memory device having a large number of word line enable signal lines NWE.

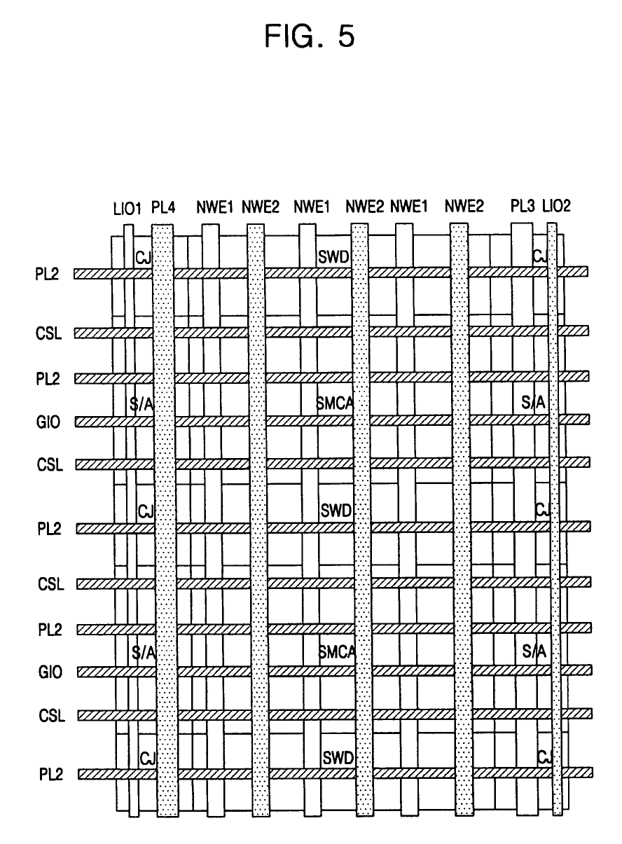

FIG. 5 is a schematic view illustrating a signal line arrangement of a semiconductor memory device according to a second embodiment of the present invention. In FIGS. 1 and 5, like references and reference numerals denote like functions and lines. In FIG. 5, the column selecting signal lines CSL, the global data IO lines GIO and the second power lines PL2 are arranged on the second layer in the same way as those of FIG. 3. The local data IO lines LIO, the first power lines PL1, and the word line enable signal lines NWE are alternately arranged on the first and third layers. That is, the local data IO lines LIO, the first power lines PL1, and the word line enable signal lines NWE are divided into first lines NWE1, LIO1 and PL3 and second lines NWE2, LIO2, and PL4 which are arranged to be alternated in a transverse direction. The first lines NWE 1, LIO 1 and PL3 are arranged on the first layer in a longitudinal direction, and the second lines NWE2, LIO2, and PL4 are arranged on the second layer in a longitudinal direction. The signal line arrangement of FIG. 5 is suitable for a semiconductor memory device having a large number of word line enable signal lines and other local data IO lines and power lines PL1.

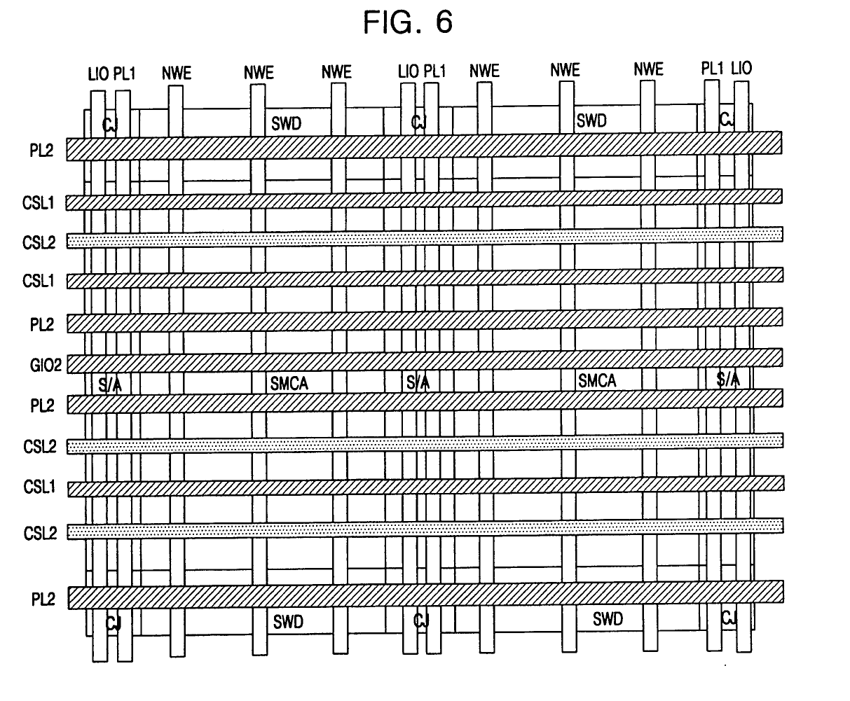

FIG. 6 is a schematic view illustrating a signal line arrangement of a semiconductor memory device according to a third embodiment of the present invention. In FIGS. 1 and 6, like references and reference numerals denote like functions and lines. In FIG. 6, the word line enable signal lines NWE, the local data IO lines LIO, and the first power lines PL1 are arranged on the first layer in the same way as those of FIG. 3, and the global data IO lines GIO and the second power lines PL2 are arranged on the second layer in the same way as those of FIG. 3. The column selecting signal lines CSL are alternately arranged on the second and third layers. That is, the column selecting signal lines CSL are divided into first column selecting signal lines CSL1 and second column selecting signal lines CSL2, which are arranged to be alternated in a longitudinal direction. The first column selecting signal lines CSL1 are arranged on the second layer in a transverse direction, and the second column selecting signal lines CSL2 are arranged on the third layer in a transverse direction. The signal line arrangement of FIG. 5 is suitable for a semiconductor memory device having a large number of column selecting signal lines CSL.

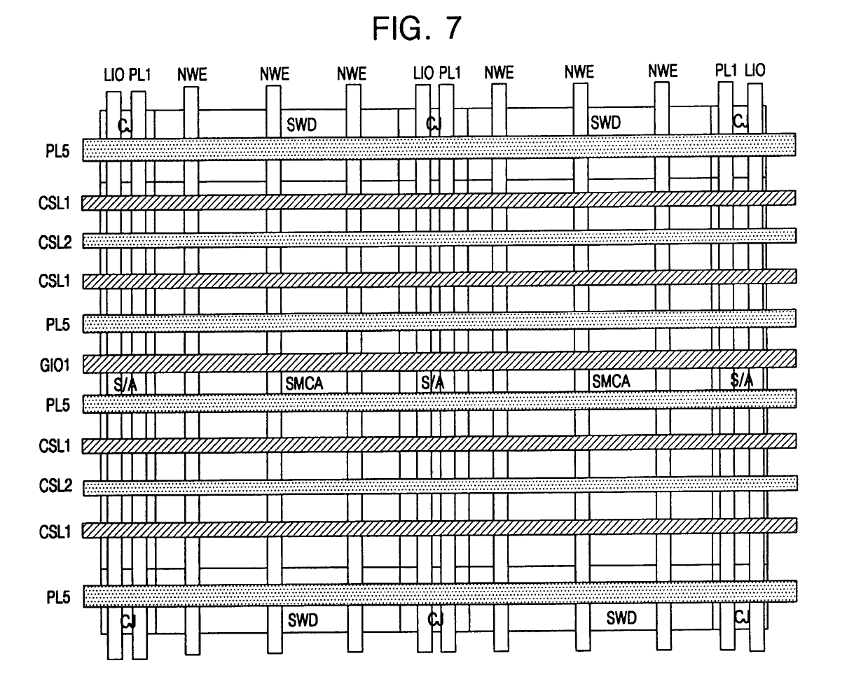

FIG. 7 is a schematic view illustrating a signal line arrangement of a semiconductor memory device according to a fourth embodiment of the present invention. In FIGS. 1 and 7, like references and reference numerals denote like functions and lines. In FIG. 7, the word line enable signal lines NWE, the local data IO lines LIO, and the first power lines PL1 are arranged on the first layer in the same way as those of FIG. 3. The column selecting signal lines CSL, the global data IO lines GIO and the second power lines PL2 are alternately arranged on the second and third layers. That is, column selecting signal lines CSL, the global data IO lines GIO and the second power lines PL2 are divided into first lines CSL1, GIO1 and PL5 and second lines CSL2, GIO2 and PL6 which are arranged to be alternated in a longitudinal direction. The first lines CSL1, GIO1 and PL5 are arranged on the second layer in a transverse direction, and the second lines CSL2, GIO2 and PL6 are arranged on the third layer in a transverse direction. The signal line arrangement of FIG. 7 is suitable for a semiconductor memory device in which it is not easy to arrange the column selecting signal lines CSL and the other lines GIO and PL2 because the other lines GIO and PL2 as well as the column selecting signal lines CSL, which should be arranged on the same metal layer, are many in number.

According to the signal line arrangements of FIGS. 4 to 7, the signal lines arranged on the same layer have enough line width and line interval such that an additional metal layer, i.e., a third layer is added above the first and second layers and signal lines are alternately arranged on the third layer and the first (or second) layer. Therefore, loading and coupling effect of the signal lines are decreased, thereby achieving easier process for the signal lines. Here, in the signal line arrangements of FIGS. 4 to 7, the signal lines arranged on the first (or second) layer and the signal lines arranged on the third layer have the same electrical resistance, i.e., loading but different line width or different line cross-sectional area. It is because loading of the signal lines is determined by characteristics of the metal layer and capacitance resulting from affection of adjacent metal layers as well as line width or line cross-sectional area of the signal lines, and the respective metal layers have different characteristics and capacitances. Location of the signal lines to be arranged on the first to third layers may be changed by a user so that the respective signal lines may have maximum line width and line interval.

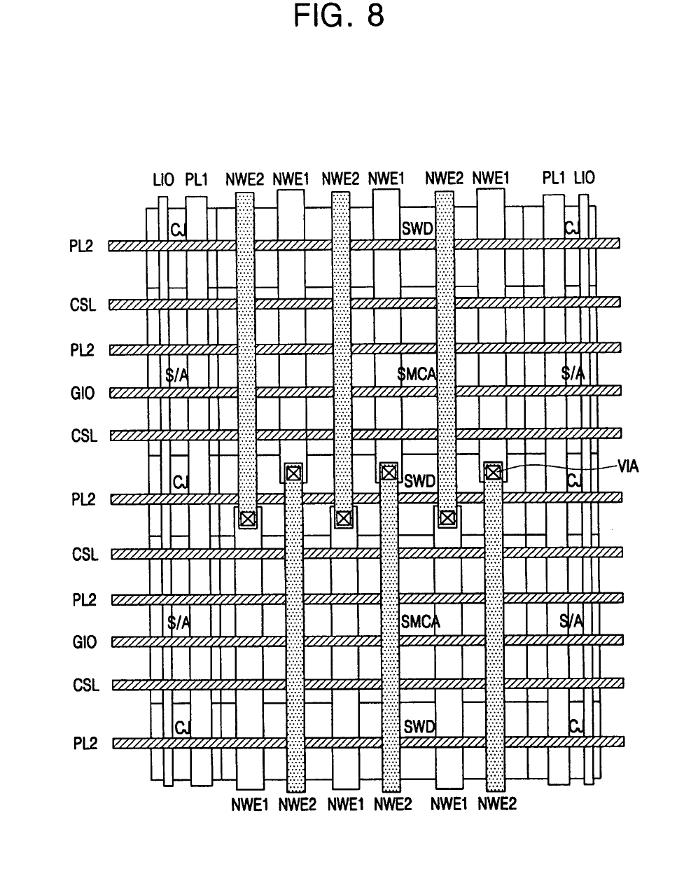

FIG. 8 is a schematic view illustrating signal line arrangement of a semiconductor memory device according to a fifth embodiment of the present invention. In FIGS. 1 and 8, like references and reference numerals denote like functions and lines. The local data IO lines LIO and the first power lines PL1 are arranged on the first layer in the same way as those of FIG. 3, and the column selecting signal lines CSL, the global data IO lines GIO and the second power lines PL2 are arranged on the second layer in the same way as those of FIG. 3. The word line enable signal lines NWE are divided into first word line enable signals NWE1 and second word line enable signal lines NWE2 which are arranged to be alternated above and below and right and left. In more detail, the word line enable signal lines NWE are divided such that the respective first word line enable signal lines NWE1 are arranged between the second word line enable signal lines NWE2 of the same word line enable signal line NWE and between the second word line enable signal lines NWE2 of the adjacent word line enable signal line NWE, and the respective second word line enable signal lines NWE2 are arranged between the first word line enable signal lines NWE1 of the same word line enable signal line NWE and between the first word line enable signal lines NWE1 of the adjacent word line enable signal line NWE.

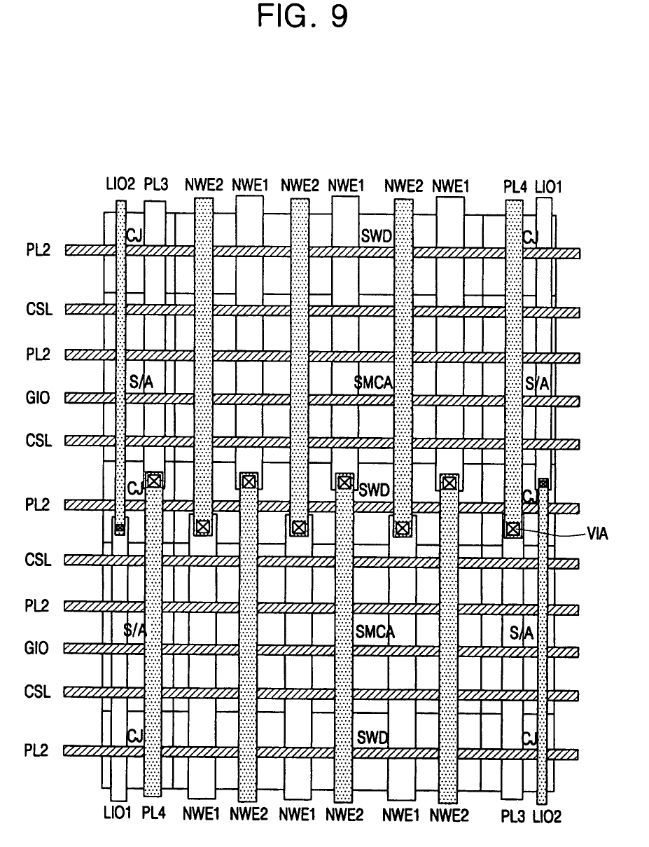

The first word line enable signal lines NWE1 are arranged on the first layer in a longitudinal direction, and the second word line enable signal lines NWE2 are arranged in a longitudinal direction on portions of the third layer above regions where the first word line enable signal lines NWE1 are not arranged. One end of the first word line enable signal line NWE1 adjacent to the second word line enable signal line NWE2 and one end of the second word line enable signal line NWE2 adjacent to the first word line enable signal line NWE1 are arranged to overlap above the sub word line driver region SWD and coupled to each other by a via plug VIA. The signal lines are alternated above and below on the same line, and the first and second word line enable signal lines NWE1 and NWE2 which are coupled through the via plug VIA transmit the same signal. Here, the area where the first and second word line enable signal lines NWE1 and NWE2 overlap is enough small to correspond to area of the via plug VIA. The signal line arrangement of FIG. 8 is suitable for a semiconductor memory device in which it is not easy to arrange word line enable signal lines NWE because the word line enable signal lines NWE, which should be arranged on the same metal layer, are many in number. FIG. 9 is a schematic view illustrating signal line arrangement of a semiconductor memory device according to a sixth embodiment of the present invention. In FIGS. 1 and 9, like references and reference numerals denote like functions and lines. The column selecting signal lines CSL, the global data IO lines GIO and the second power lines PL2 are arranged on the second layer in the same way as those of FIG. 3. The local data IO lines LIO, the first power lines PL1, and the word line enable signal lines NWE are arranged as follows. The local data IO lines LIO, the first power lines PL1, and the word line enable signal lines NWE are divided into first lines NWE1, LIO1 and PL3 and second lines NWE2, LIO2, and PL4 which are arranged to be alternated above and below and right and left. In more detail, the respective first lines NWE1, LIO1 and PL3 are arranged between the second lines NWE2, LIO2 and PL4 of the same signal lines NWE, LIO and PL1 and between the second lines NWE2, LIO2 and PL4 of the adjacent signal lines NWE, LIO and PL1, and the respective second lines NWE2, LIO2, and PL4 are arranged between the first lines NWE1, LIO1 and PL3 of the same signal lines NWE, LIO and PL1 and between the first lines NWE1, LIO1 and PL3 of the adjacent signal lines NWE, LIO and PL1. The first lines NWE1, LIO1 and PL3 are arranged on the first layer in a longitudinal direction, and the second lines NWE2, LIO2 and PL4 are arranged in a longitudinal direction on portion of the third layer above regions where the first lines NWE1, LIO1 and PL3 are not arranged.

One end of the second line NWE2 adjacent to the first line NWE1 and one end of the first line NWE1 adjacent to the second line NWE2 are arranged to overlap above the sub word line driver region SWD and then coupled to each other by a via plug VIA. One ends of the second lines LIO2 and PL4 adjacent to the first lines LIO1 and PL3 and one ends of the first lines LIO1 and PL3 adjacent to the second lines LIO2 and PL4 are arranged to overlap above the conjunction region CJ and then coupled to each other by a via plug VIA. The signal line arrangement of FIG. 9 is suitable for a semiconductor memory device in which it is not easy to arrange the word line enable signal lines NWE, the local data IO lines LIO, and the first power lines PL1 because the local data IO lines LIO and the first power lines PL1 as well as the word line enable signal lines NWE, which should be arranged on the same metal layer, are many in number.

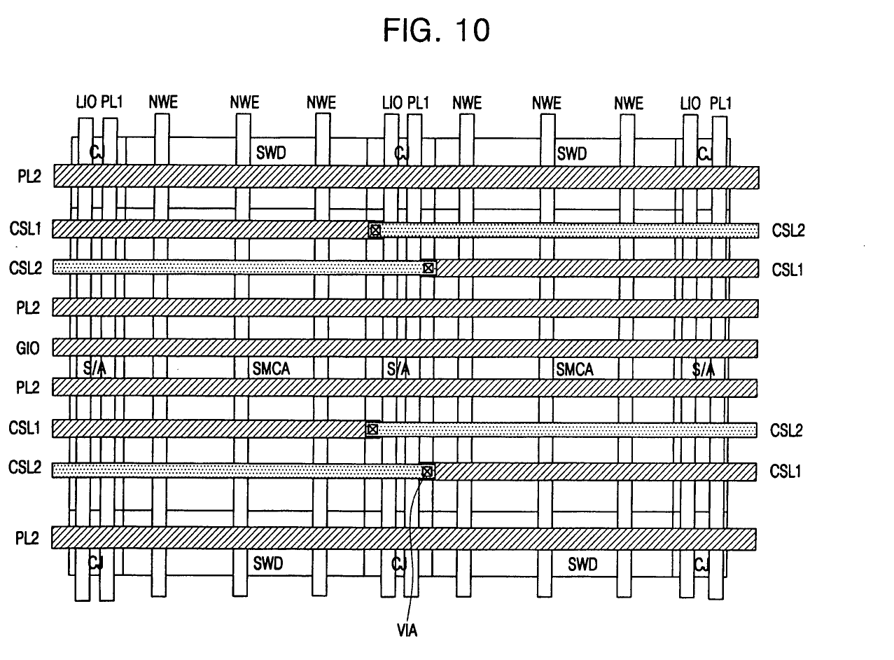

FIG. 10 is a schematic view illustrating signal line arrangement of a semiconductor memory device according to a seventh embodiment of the present invention. In FIGS. 1 and 10, like references and reference numerals denote like functions and lines. The word line enable signal lines NWE, the local data IO lines LIO, and the first power lines PL1 are arranged on the first layer in the same way as those of FIG. 3, and the global data IO lines GIO and the second power lines PL2 are arranged on the second layer in the same way as those of FIG. 3. The column selecting signal lines CSL are divided into first column selecting signal lines CSL1 and second column selecting signal lines CSL2 which are arranged to be alternated above and below and right and left. In more detail, the column selecting signal lines CSL are divided such that the respective first column selecting signal lines CSL1 are arranged between the second column selecting signal lines CSL2 of the same column selecting signal lines CSL and between the second column selecting signal lines CSL2 of the adjacent column selecting signal lines CSL, and the respective second column selecting signal lines CSL2 are arranged between the first column selecting signal lines CSL1 of the same column selecting signal lines CSL and between the first column selecting signal lines CSL1 of the adjacent column selecting signal lines CSL. The first column selecting signal lines CSL1 are arranged on the second layer in a transverse direction, and the second column selecting signal lines CSL2 are arranged in a transverse direction on portions of the third layer above regions where the first column selecting signal lines CSL1 are not arranged. One end of the first column selecting signal lines CSL1 adjacent to the second column selecting signal lines CSL2 and one end of the second column selecting signal lines CSL2 adjacent to the first column selecting signal lines CSL1 are arranged to overlap above the sense amplifier region S/A and then coupled to each other by a via plug VIA. The signal line arrangement of FIG. 10 is suitable for a semiconductor memory device in which it is not easy to arrange the column selecting signal lines CSL because the column selecting signal lines CSL, which should be arranged on the same metal layer, is many in number.

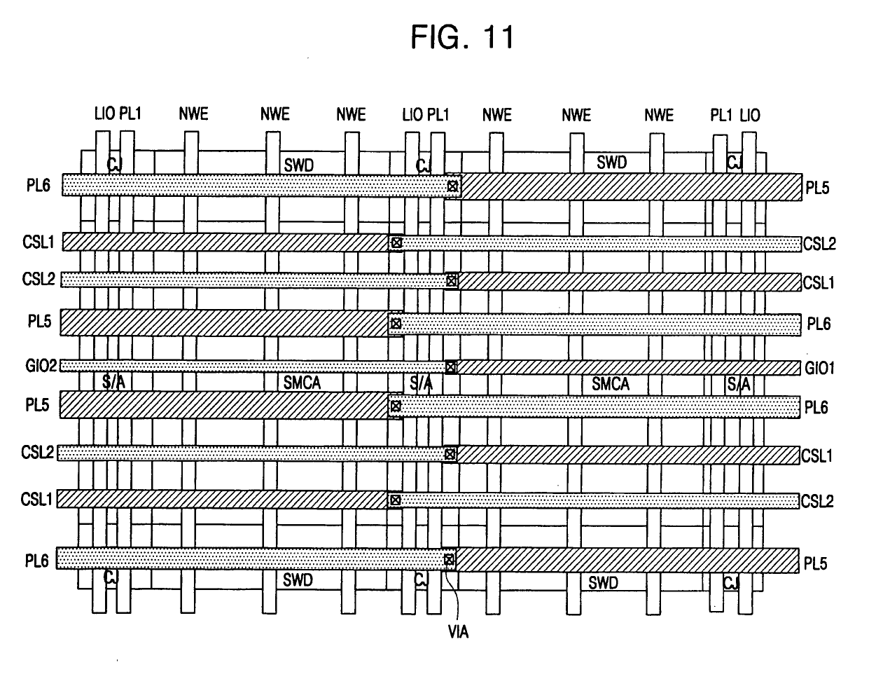

FIG. 11 is a schematic view illustrating signal line arrangement of a semiconductor memory device according to an eighth embodiment of the present invention. In FIGS. 1 and 11, like references and reference numerals denote like functions and lines. The word line enable signal lines NWE, the local data IO lines LIO, and the first power lines PL1 are arranged on the first layer in the same way as those of FIG. 3. The column selecting signal lines CSL, the global data IO lines GIO and the second power lines PL2 are arranged as follows. The column selecting signal lines CSL, the global data IO lines GIO and the second power lines PL2 into first lines CSL1, GIO1 and PL5 and second lines CSL2, GIO2 and PL6 which are arranged above and below and right and left. In more detail, the respective first lines CSL1, GIO1 and PL5 are arranged between the second lines CSL2, GIO2 and PL6 of the same signal lines CSL, GIO and PL1 and between the second lines CSL2, GIO2 and PL6 of the adjacent signal lines CSL, GIO and PL1, and the respective second lines CSL2, GIO2 and PL6 are arranged between the first lines CSL1, GIO1 and PL5 of the same signal lines CSL, GIO and PL1 and between the first lines CSL1, GIO1 and PL5 of the adjacent signal lines CSL, GIO and PL1. The first lines CSL1, GIO1 and PL5 are arranged on the first layer in a transverse direction, and the second lines CSL2, GIO2 and PL6 are arranged in a transverse direction on portion of the third layer above regions where the first lines CSL1, GIO1 and PL5 are not arranged. One ends of the second lines CSL2, GIO2 and PL6 adjacent to the first lines CSL1, GIO1 and PL5 and one ends of the first lines CSL1, GIO1 and PL5 adjacent to the second lines CSL2, GIO2 and PL6 are arranged to overlap above the sense amplifier region S/A or the conjunction region CJ and then coupled to each other by a via plug VIA. The signal line arrangement of FIG. 11 is suitable for a semiconductor memory device in which it is not easy to arrange the column selecting signal lines CSL, the global data IO lines and the second power lines PL2 because the global data IO lines and the second power lines PL2 as well as the column selecting signal lines CSL, which should be arranged on the same metal layer, are many in number.

In the embodiments of FIGS. 8 to 11, it has been described that the respective signal lines includes one first line and one second line, but the respective signal lines can include a plurality of first signal lines and a plurality of second lines throughout the memory cell array region. According to the signal line arrangements of FIGS. 8 to 11, the signal lines arranged on the same layer have enough line width and line interval such that an additional metal layer, i.e., a third layer is added above the first and second layers and signal lines are arranged to be alternated above and below and right and left on the third layer and the first (or second) layer. Therefore, loading and coupling effect of the signal lines are decreased, thereby achieving easier process for the signal lines. The respective signal lines which transmit the same signal are formed by coupling first lines arranged on the first (or second) layer to the second lines arranged on the third layer, and thus all of the signal lines which transmit the same signal have the same loading without a loading matching process. Thus, there is an advantage in that screw between the signal lines, which transmit the same signal, is prevented in advance.

According to the signal line arrangements of FIGS. 4 to 11, a lot number of signal lines are efficiently arranged in case where the number of the signal lines arranged in a restricted area of the memory cell array is increased due to high integration and high capacity. However, as the semiconductor memory device is high integrated and has high capacity, length of the signal lines, which are arranged throughout the memory cell array region, can be increased. Thus, a semiconductor memory device suitable for this case is suggested below. For the description convenience, the column selecting signal line CSL is used as an example of the signal line having increased length, and a signal line arrangement for reducing resistance, i.e., loading of the column selecting signal line CSL will be described below.

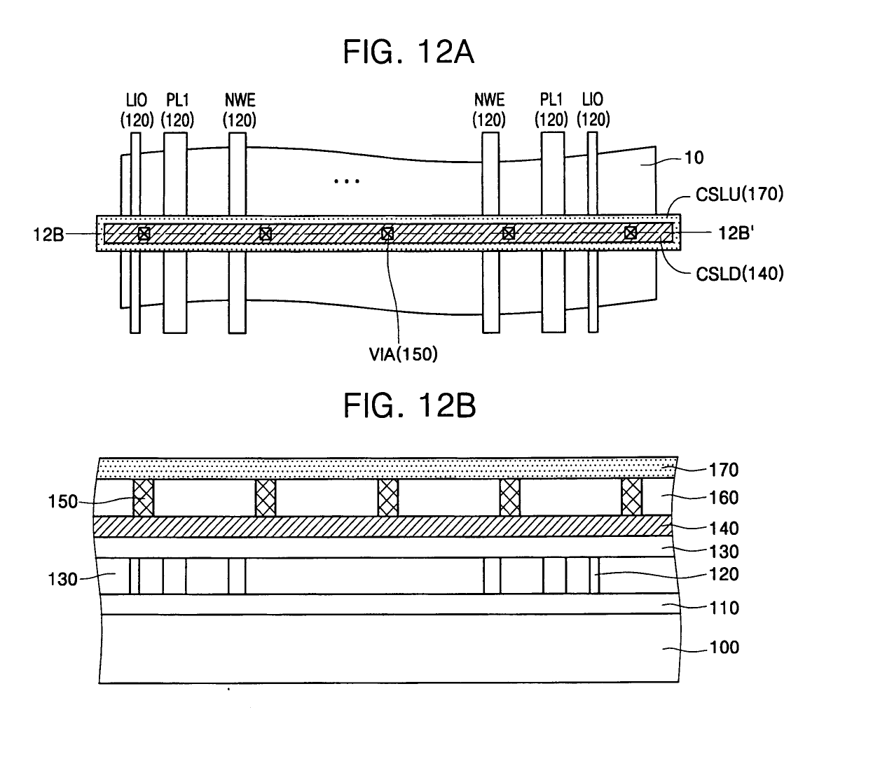

FIGS. 12A and 12B are schematic views illustrating signal line arrangement of a semiconductor memory device according to a ninth embodiment of the present invention. FIG. 12A is a plane view illustrating the column selecting signal line CSL, and FIG. 12B is a cross-sectional view taken along line 12B-12B′ of FIG. 12A. In FIGS. 1 and 12A and 12B, like references and reference numerals denote like functions and lines. Referring to FIG. 12A, each column selecting signal line CSL includes a lower column selecting signal line CSLD and an upper column selecting signal line CSLU, and the upper column selecting signal line CSLU is arranged to overlap over the lower column selecting signal line CSLD. A plurality of via plugs VIA are arranged at a predetermined interval between the upper and lower column selecting signal lines CSLU and CSLD. Thus, the upper and lower column selecting signal lines CSLU and CSLD are electrically connected to transmit the same signal. Here, the upper and lower column selecting signal lines CSLU and CSLD are similar to each other in length. Even though not shown, one end of the upper column selecting signal line CSLU and one end of the lower column selecting signal line CSLD are connected to the column decoder 20 which is arranged around an edge of the memory cell array region 10.

Referring to FIG. 12B, a first metal layer 120 which forms the signal lines NWE, LIO and PL1 perpendicular to the column selecting signal lines CSL is formed above a semiconductor substrate 100. A second metal layer 140, which forms the lower column selecting signal line CSLD, is formed above the first metal layer 120. A third metal layer 170, which forms the upper column selecting signal line CSLU is formed above the second metal layer 140. Interlayer insulators 110, 130 and 160 are formed between the first metal layer 120 and the semiconductor substrate 100, between the first metal layer 120 and the second metal layer 140, and between the second metal layer 140 and the third metal layer 170, respectively.

The upper and lower column selecting signal lines CSLU and CSLD are connected by the via plug 150 which penetrates the interlayer insulator 160. The embodiment of FIGS. 12A and 12B reduces resistance, i.e., loading of the column selecting signal line CSL such that the column selecting signal line CSL is composed of the upper and lower column selecting signal lines CSLU and CSLD which are electrically connected.

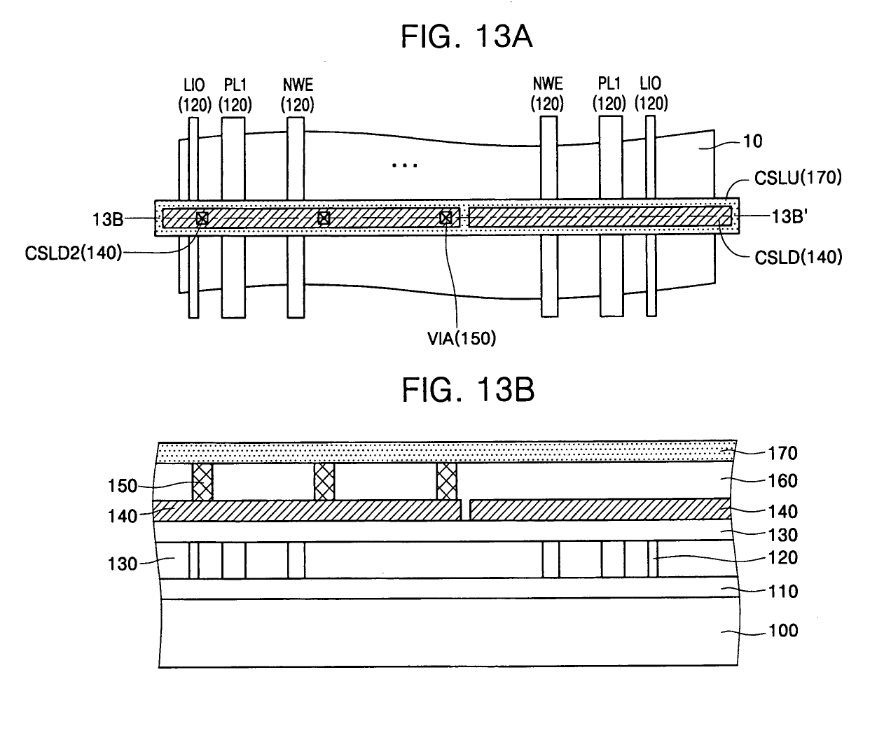

FIGS. 13A and 13B are schematic views illustrating signal line arrangement of a semiconductor memory device according to a tenth embodiment of the present invention. FIG. 13A is a plane view illustrating the column selecting signal line CSL, and FIG. 13B is a cross-sectional view taken along line 13B-12B′ of FIG. 13A.

In FIGS. 1 and 13A and 13B, like references and reference numerals denote like functions and lines. Referring to FIG. 13A, each column selecting signal line CSL includes a lower column selecting signal line CSLD and an upper column selecting signal line CSLU like that of FIG. 12A, but the lower column selecting signal line CSLD includes a first lower column selecting signal line CSLD1 which is adjacent to the column decoder 20 and a second lower column selecting signal line CSLD2 which is apart from the column decoder 20. The first lower column selecting signal line CSLD1 is connected directly to the column decoder 20, and the second lower column selecting signal line CSLD2 is indirectly connected to the column decoder through the upper column selecting signal line CSLU. That is, a plurality of via plugs VIA are arranged at a predetermined interval between the upper column selecting signal line CSLU and the second lower column selecting signal line CSLD2, so that the upper column selecting signal line CSLU and the second lower column selecting signal line CSLD2 are electrically connected to transmit the same signal.

Referring to FIG. 13B, a first metal layer 120 which forms the signal lines NWE, LIO and PL1 perpendicular to the column selecting signal lines CSL is formed above a semiconductor substrate 100. A second metal layer 140 which forms the first and second lower column selecting signal lines CSLD1 and CSLD2 is formed above the first metal layer 120. A third metal layer 170, which forms the upper column selecting signal line CSLU is formed above the second metal layer 140. Interlayer insulators 110, 130 and 160 are formed between the first metal layer 120 and the semiconductor substrate 100, between the first metal layer 120 and the second metal layer 140, and between the second metal layer 140 and the third metal layer 170, respectively. The upper column selecting signal lines CSLU and the second lower column selecting signal line CSLD2 are connected by the via plug 150 which penetrates the interlayer insulator 160. The embodiment of FIGS. 13A and 13B mitigates signal distortion phenomenon resulting from approach time difference according to a distance from the column decoder.

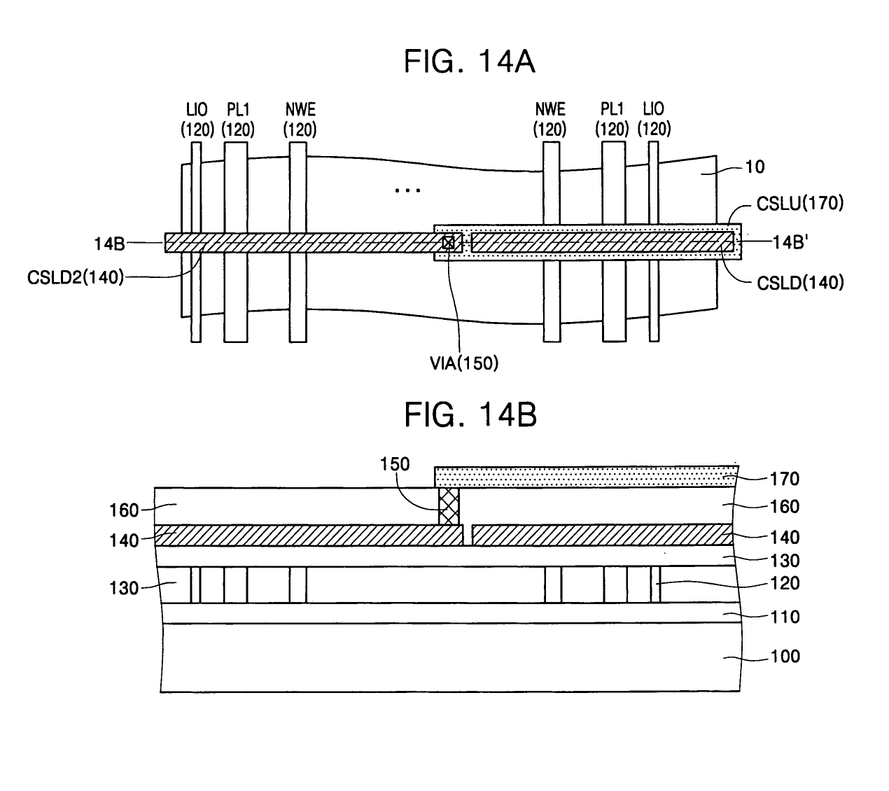

FIGS. 14A and 14B are schematic views illustrating signal line arrangement of a semiconductor memory device according to an eleventh embodiment of the present invention. FIG. 14A is a plane view illustrating the column selecting signal line CSL, and FIG. 14B is a cross-sectional view taken along line 14B-14B′ of FIG. 14A. In FIGS. 1 and 14A and 14B, like references and reference numerals denote like functions and lines. Referring to FIG. 14A, each column selecting signal line CSL includes a lower column selecting signal line CSLD and an upper column selecting signal line CSLU like that of FIG. 13A, but the lower column selecting signal line CSLD includes a first lower column selecting signal line CSLD1 and a second lower column selecting signal line CSLD2. The first lower column selecting signal line CSLD1 is connected directly to the column decoder 20, and the second lower column selecting signal line CSLD2 is connected to the column decoder 20 through the upper column selecting signal line CSLU. However, the second lower column selecting signal line CSLD2 and the upper column selecting signal line CSLU are connected through one via plug VIA. Preferably, the upper column selecting signal line CSLU is arranged to overlap the whole region of the first lower column selecting signal line CSLD1 and overlap part of the second lower column selecting signal lines CSLD2. One the via plug VIA is arranged on one end of the second lower column selecting signal line CSLD2 adjacent to the first lower column selecting signal line CSLD1. Here, a region where the second lower column selecting signal line CSLD2 and the upper column selecting signal line CSLU overlap is an area to correspond to an area of one via plug VIA.

Referring to FIG. 14B, a first metal layer 120 which forms the signal lines NWE, LIO and PL1 perpendicular to the column selecting signal lines CSL is formed above a semiconductor substrate 100. A second metal layer 140 which forms the first and second lower column selecting signal lines CSLD1 and CSLD2 is formed above the first metal layer 120. A third metal layer 170, which forms the upper column selecting signal line CSLU is formed above the second metal layer 140. Interlayer insulators 110, 130 and 160 are formed between the first metal layer 120 and the semiconductor substrate 100, between the first metal layer 120 and the second metal layer 140, and between the second metal layer 140 and the third metal layer 170, respectively. The upper column selecting signal lines CSLU and the second lower column selecting signal line CSLD2 are connected by one via plug 150 which penetrates the interlayer insulator 160.

The embodiment of FIGS. 14A and 14B mitigates signal distortion phenomenon resulting from approach time difference according to a distance from the column decoder. The signal line arrangements of FIGS. 12A to 14A, it is preferred that the upper column selecting signal line has lower electrical resistance, i.e., loading than the lower column selecting signal line. For example, the upper column selecting signal line may be made of a material having lower specific resistance than the lower column selecting signal line or have larger cross-sectional area than the lower column selecting signal line. Thus, the column selecting signal line can transmit a signal through the upper column selecting signal line faster than through the lower column selecting signal line. As a result, signal distortion phenomenon resulting from approach time difference according to a distance from the column decoder is more reduced.

In the signal line arrangements of FIGS. 12A and 12B to 14A and 14B, the column selecting signal line CSL is used as a signal line having increased length, but the word line enable signal line NWE, the global data 10 line GIO, or the local data 10 line can be used as a signal line having increased length. In the embodiments of FIG. 4 to FIGS. 14A and 14B, it has been described that the word line enable signal line NWE is arranged on the first layer and the column selecting signal line CSL is arranged on the second layer. But, layers where the signal lines NWE and CSL are arranged may be changed. Also, it has been described that the local data 10 line LIO and the power line PL1 are used as a signal line which is arranged on the same layer as the word line enable signal line NWE. But, different signal lines may be arranged on the same layer as the word line enable signal line NWE. The signal lines arranged in the same direction as the column selecting signal line CSL may be arranged in a way described above.

As described herein before, the semiconductor memory device can have enough line width and line interval by adding a metal layer and arranging part of the signal lines on the metal layer. As a result, since the semiconductor memory device has enough ling width and line interval even though it is high integrated and has high capacity, the process margin is obtained, and loading of the signal line is reduced, whereby it can operate at high speed.

Even though the semiconductor memory device increases in size and so length of the signal line is increased, the signal lines are arranged on at least two metal layers, so that resistance and capacitance, i.e., loading of the signal line can be reduced. Thus, signal distortion phenomenon resulting from increment of length of the signal line is minimized, whereby operation characteristics of the semiconductor memory device can be improved.

1. A semiconductor memory device having a memory cell array, comprising:
a plurality of first signal lines arranged on the memory cell array in the same direction; and
a plurality of second signal lines arranged on the memory cell array in a perpendicular direction to the first signal lines,
wherein the first signal lines are alternately arranged on at least two layers, and the second signal lines are arranged on a layer where the first signal lines are not arranged.

2. The memory device of claim 1, wherein the first signal lines and the second signal lines are metal lines.

3. The memory device of claim 2, wherein the second signal lines are arranged on a layer between the two layers which the first signal lines are arranged on.

4. The memory device of claim 2, wherein the second signal lines are arranged on a layer above the two layers which the first signal lines are arranged on.

5. The memory device of claim 2, wherein the second signal lines are arranged on a layer under the two layers which the first signal lines are arranged on.

6. The memory device of claim 2, wherein the first signal lines are word line enable signal lines and the second signal lines are column selecting signal lines.

7. The memory device of claim 2, wherein the second signal lines are word line enable signal lines and the first signal lines are column selecting signal lines.

8. A semiconductor memory device having a memory cell array, comprising:
a plurality of first signal lines, each of the plurality of first signal lines including a first line and a second line which are arranged on different layers on the memory cell array; and
a plurality of second signal lines arranged on a layer where the first signal lines are not arranged in a perpendicular direction to the first signal lines on the memory cell array,
wherein the first line of the first signal line is arranged between the second lines of the same first signal line and between the second lines of the adjacent first signal lines, and the second line is arranged between the first lines of the same first signal line and between the first lines of the adjacent first signal lines.

9. The device of claim 8, wherein the first and second lines of the first signal line transmit the same signal.

10. The memory device of claim 8, wherein the second signal lines are arranged on a layer between the two layers which the first signal lines are arranged on.

11. The memory device of claim 8, wherein the second signal lines are arranged on a layer above the two layers which the first signal lines are arranged on.

12. The memory device of claim 8, wherein the second signal lines are arranged on a layer under the two layers which the first signal lines are arranged on.

13. The memory device of claim 8, wherein the first signal lines and the second signal lines are metal lines.

14. The device of claim 8, wherein the first signal line is a word line enable signal line, and the second signal line is a column selecting signal line.

15. The device of claim 14, wherein the memory cell array includes
sub memory cell array blocks having memory cells connected between a sub word line and a bit line which is arranged in a perpendicular direction to the sub word line;
sub word line driver blocks arranged above and below between the sub memory cell array blocks;
sense amplifier blocks arranged right and left between the sub memory cell array blocks; and
conjunction regions arranged right and left between the sub word line driver blocks,
wherein the first and second lines of the word line enable signal line are arranged above the sub memory cell array blocks and the sub word line driver blocks, and the first and second lines are connected above the sub word line driver blocks.

16. The device of claim 14, wherein the first signal line further includes a third signal line or a first power line which is arranged in the same direction as the word line enable signal line.

17. The device of claim 16, wherein the first and second lines of the third signal line or the first power line are arranged above the sense amplifier blocks and the conjunction regions, and the first and second lines are connected above the conjunction regions through the via plugs.

18. The device of claim 8, wherein the first signal line is a columns selecting signal line, and the second signal line is a word line enable signal line.

19. The device of claim 18, wherein the memory cell array includes sub memory cell array blocks having memory cells connected between a sub word line and a bit line which is arranged in a perpendicular direction to the sub word line;
sub word line driver blocks arranged above and below between the sub memory cell array blocks;
sense amplifier blocks arranged right and left between the sub memory cell array blocks; and
conjunction regions arranged right and left between the sub word line driver blocks,
wherein the first and second lines of the column selecting signal line are arranged above the sub memory cell array blocks and the sense amplifier blocks, and the first and second lines are connected above the sense amplifier blocks.

20. The device of claim 18, wherein the first signal line further includes a fourth signal line or a second power line which is arranged in the same direction as the column selecting signal line.

21. The device of claim 20, wherein the first and second lines of the fourth signal line or the second power line are arranged above the sub memory cell array block and the sense amplifier blocks or the sub word line driver blocks and the conjunction regions, and the first and second lines are connected above the sense amplifier blocks or the conjunction regions.

22. A semiconductor memory device having a memory cell array, comprising:
a plurality of first signal lines, each of the plurality of the first signal lines including a lower line and an upper line which are arranged on different layers above the memory cell array; and
a plurality of second signal lines which are arranged on a layer where the first signal lines are not arranged, in a perpendicular direction to the first signal lines above the memory cell array,
wherein the upper line of the first signal line is arranged to overlap the lower line of the same first signal line.

23. The memory device of claim 22, wherein the second signal lines are arranged on a layer between the two layers which the first signal lines are arranged on.

24. The memory device of claim 22, wherein the second signal lines are arranged on a layer above the two layers which the first signal lines are arranged on.

25. The memory device of claim 22, wherein the second signal lines are arranged on a layer under the two layers which the first signal lines are arranged on.

26. The memory device of claim 22, wherein the first signal lines and the second signal lines are metal lines.

27. The device of claim 22, wherein length of the upper line is similar to length of the lower line.

28. The device of claim 22, wherein the lower line includes a first lower line and a second lower line, which is arranged apart from the first lower line, and the upper line is connected to the second lower line without being connected to the first lower line.

29. The device of claim 28, wherein the upper line is connected to the second lower line through at least two via plugs.

30. The device of claim 28, wherein the upper line is connected to one end of the second lower line adjacent to the first lower line through the via plug.

31. The device of claim 22, wherein the upper line has lower electrical resistance than the lower line.

32. The device of claim 31, wherein the upper line is made of a material having lower specific resistance than the lower line.

33. The device of claim 31, wherein the upper line has larger cross-sectional area than the lower line.
